(19) United States
(12) Patent Application Publication
(10) Pub. No.: US 2008/0171436 A1
(43) Pub. Date: Jul. 17, 2008

(54) METHODS OF DEPOSITING A RUTHENIUM FILM

(75) Inventors: Wonyong Koh, Daejeon (KR); Chun Soo Lee, Daejeon (KR)

Correspondence Address: KNOBBE MARTENS OLSON & BEAR LLP, 2040 MAIN STREET, FOURTEENTH FLOOR, IRVINE, CA, 92614, US

(73) Assignee: ASM Genitech Korea Ltd., Cheonan-si (KR)

(21) Appl. No.: 11/972,081

(22) Filed: Jan. 10, 2008

(30) Foreign Application Priority Data
Jan. 11, 2007 (KR) 10-2007-0003274

(51) Int. Cl. H01L 21/44

(52) U.S. Cl. 438/681; 257/E21.478

(57) ABSTRACT

Cyclical methods of depositing a ruthenium film on a substrate are provided. In one process, each cycle includes supplying a ruthenium organometallic compound gas to the reactor; purging the reactor; supplying a ruthenium tetroxide (RuO₄) gas to the reactor; and purging the reactor. In another process, each cycle includes simultaneously supplying RuO₄ and a reducing agent gas; purging; and supplying a reducing agent gas. The methods provide a high deposition rate while providing good step coverage over structures having a high aspect ratio.

### CROSS-REFERENCE TO RELATED APPLICATIONS

This application claims priority to and the benefit of Korean Patent Application No. 10-2007-0003274 filed in the Korean Intellectual Property Office on Jan. 11, 2007, the entire contents of which are incorporated herein by reference.

### FIELD OF THE INVENTION

The present invention relates to a method of forming a layer on a substrate. Particularly, the present invention relates to methods of forming a ruthenium layer on a substrate.

### BACKGROUND OF THE INVENTION

A ruthenium metal layer has been researched for use as an electrode material, for example, a gate electrode material for memory devices. Recently, various applications of ruthenium (e.g., as an electrode material for a DRAM and a diffusion barrier for a copper line) have drawn attention. When a ruthenium layer forms an electrode on a structure having a high aspect ratio (e.g., a DRAM capacitor), the ruthenium layer typically should have a thickness of at least about 10 nm. A physical deposition method can be used to form a ruthenium film. An exemplary physical deposition method is a sputtering method, but sputtering tends not to exhibit good step coverage, particularly in high aspect ratio applications like DRAM capacitors.

Chemical vapor deposition (CVD) methods of forming thin films of ruthenium (Ru) or ruthenium dioxide (RuO₂) are also known. Such CVD methods use an organometallic compound of ruthenium, such as a ruthenium cyclopentadienyl compound or bis(ethylcyclopentadienyl)ruthenium (Ru(EtCp)₂) and oxygen (O₂) gas as reactants. An exemplary method is disclosed by Park et al., “Metallorganic Chemical Vapor Deposition of Ru and RuO₂ Using Ruthenocene Precursor and Oxygen Gas,” J. Electrochem. Soc., 147[1], 203, 2000. CVD, employing simultaneous provision of multiple reactants, also suffers from less than perfect conformality.

Atomic layer deposition (ALD) methods of forming ruthenium thin films are also known. Generally, ALD involves sequential introduction of separate pulses of at least two reactants until a layer of a desired thickness is deposited through self-limiting adsorption of monolayers of materials on a substrate surface. For example, in forming a thin film including an AB material, a cycle of four sequential steps of: (1) a first reactant gas A supply; (2) an inert purge gas supply; (3) a second reactant gas B supply; and (4) an inert purge gas supply is repeated. Examples of the inert gas are argon (Ar), nitrogen (N₂), and helium (He). An exemplary atomic layer deposition method is disclosed by Aaltonen et al., “Ruthenium Thin Film Grown by Atomic Layer Deposition,” Chem. Vap. Deposition 9[1], 45 2003.

Metallorganic precursors, such as those employed in the above-referenced disclosures, have a tendency to leave carbon in the Ru films. However, CVD and ALD can also be conducted using inorganic Ru precursors. Advantages of using RuO₄ as a Ru vapor precursor includes high reactivity and reduced carbon content. Vapor deposition processes involving RuO₄ are disclosed, for example, in U.S. patent publication No. 2005/0238808.

While ALD advantageously produces high step coverage, it is a relatively slow process. A typical ALD process employs 200-1000 cycles to form about 100 Å of Ru for use as an electrode in a memory cell capacitor. High surface area structures, such as DRAM designs with greater than 20:1 aspect ratio features to cover, also lengthen the time for each cycle, as extended purging is needed to fully remove reactants and by-products between reactant pulses.

Accordingly, a need exists for high step coverage deposition processes with improved rates of deposition.

The above information disclosed in this Background section is only for enhancement of understanding of the background of the invention and therefore it may contain information that does not form the prior art that is already known in this country to a person of ordinary skill in the art.

### SUMMARY OF THE INVENTION

In one embodiment, a method of depositing a ruthenium film on a substrate comprises loading a substrate into a reactor; and conducting a plurality of deposition cycles. Each cycle comprises steps of: a step of supplying a ruthenium organometallic compound gas to the reactor; a step of supplying an inert purge gas to the reactor; a step of supplying a ruthenium tetroxide (RuO₄) gas to the reactor; and a step of supplying an inert purge gas to the reactor.

In another embodiment, a method of making an electronic device comprises providing a substrate into a reaction space; and conducting a cyclical deposition on the substrate in the reaction space. Each cycle comprises providing a rutheniun organometallic compound to the substrate; removing any excess of the ruthenium organometallic compound from the reaction space; providing ruthenium tetroxide (RuO4) to the substrate; and removing any excess of the ruthenium tetroxide from the reaction space.

In yet another embodiment, a method of depositing a ruthenium film on a substrate comprises: loading a substrate in a reactor; and conducting a plurality of deposition cycles. Each cycle comprises in sequence: supplying ruthenium tetroxide (RuO4) gas and a reducing agent gas simultaneously to the reactor; first supplying an inert purge gas to the reactor; and supplying a reducing agent gas to the reactor.

### BRIEF DESCRIPTION OF THE DRAWINGS

FIG. 1 is a flowchart illustrating one embodiment of an atomic layer deposition (ALD) method of forming a ruthenium layer.

FIG. 2 is a flowchart illustrating another embodiment of an ALD method of forming a ruthenium layer.

FIG. 3A and FIG. 3B are flowcharts illustrating other embodiments of ALD methods of forming a ruthenium layer.

FIG. 4 is a flowchart illustrating yet another embodiment of an ALD method of forming a ruthenium layer.

### DETAILED DESCRIPTION OF THE PREFERRED EMBODIMENT

The present invention will be described more fully hereinafter with reference to the accompanying drawings, in which exemplary embodiments are shown. As those skilled in the art would realize, the described embodiments may be modified in various different ways, all without departing from the spirit or scope of the present invention.

As noted in the Background section, physical deposition methods (e.g., sputtering), due to their line-of-sight deposition characteristics, may form ruthenium layers without good step coverage for features having a high aspect ratio (e.g., an electrode of DRAM). A chemical vapor deposition method, although it may provide a high deposition rate, may not form a ruthenium thin film having uniform thickness and good step coverage on a structure having a high aspect ratio.

In ALD, slowness results from having to switch gases for about 200-1000 cycles of supplying reactant gases until a ruthenium layer is deposited to a thickness of about 100 Å, which is suitable for an electrode of a memory device. In addition, when a thin film is deposited on a structure (e.g., for a DRAM capacitor) with a rough surface having a plurality of protrusions and depressions with an aspect ratio of about 20:1 or greater, in each cycle it generally takes several seconds to remove excess reactants and reaction by-products from a reaction chamber. Thus, the deposition rate is relatively low, thereby resulting in low productivity. Moreover, excessive carbon may be left in the film.

Accordingly, there is a need for a deposition method that has a high deposition rate while forming a ruthenium layer having good step coverage even on a feature having a high aspect ratio.

### Ruthenium Film Formation

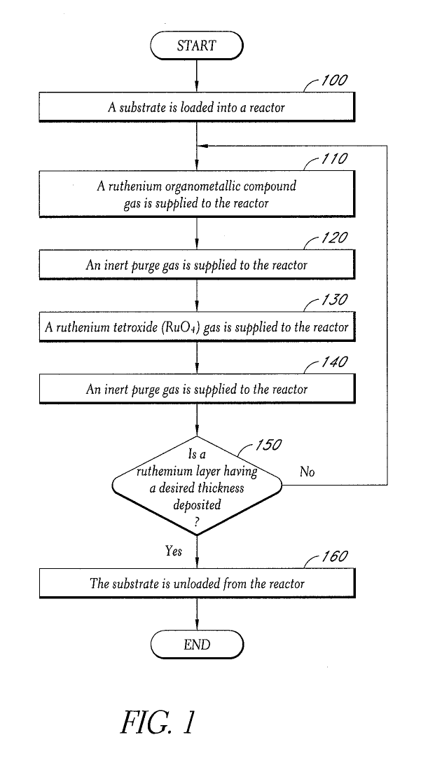

Referring to FIG. 1, a deposition method for formation of a ruthenium layer according to one embodiment will be described below. FIG. 1 is a flowchart illustrating a method of forming a ruthenium layer according to one embodiment.

At step 100, a substrate is loaded into a reactor. In one embodiment, the substrate can have at least one structure or feature having an aspect ratio of about 2:1 or greater, particularly, about 10:1 or greater, and more particularly, about 20:1 or greater. An example is a substrate with a dense pattern of features for high surface capacitor shapes in a DRAM array. The reactor can be a chemical vapor deposition reactor or an atomic layer deposition reactor. A skilled artisan will appreciate that various configurations of reactors can also be adapted for the method.

Subsequently, a deposition cycle is conducted. The cycle includes steps of: supplying a ruthenium organometallic compound gas to the reactor (step 110); supplying an inert purge gas to the reactor (step 120); supplying a ruthenium tetroxide (RuO₄) gas to the reactor (step 130); and supplying an inert purge gas to the reactor (step 140). In one embodiment, the duration of each of the steps for a typical single-wafer reactor is about 0.2 seconds to about 10 seconds. In other embodiments, the durations of the steps can vary depending on the volume and structure of the reactor. The skilled artisan will appreciate that inert gas flow can be continuous throughout the cycle(s), 110-140 or be pulsed during the purge steps 120, 140.

In the illustrated embodiment, the ruthenium organometallic compound may be a cyclopentadienyl compound of ruthenium. Examples of cyclopentadienyl compounds include, but are not limited to, bis(ethylcyclopentadienyl) ruthenium (Ru(EtCp)₂) and its derivatives. In other embodiments, any suitable ruthenium organometallic compounds may be used as long as their vapor pressure is sufficiently high for deposition.

Ruthenium tetroxide (RuO₄) gas is a strong oxidizing agent, and particularly is a stronger oxidizing agent than oxygen gas (O₂). Accordingly, the ruthenium tetroxide (RuO₄) gas can react with a ruthenium organometallic compound to form a ruthenium layer effectively. During the step 130, the ruthenium tetroxide (RuO₄) gas reacts with the ruthenium organometallic compound that has been adsorbed on the substrate during the step 110, thereby forming a ruthenium layer. Simultaneously, the ruthenium tetroxide (RuO₄) is also adsorbed on the ruthenium layer. The ruthenium tetroxide (RuO₄) adsorbed on the ruthenium layer can react with the ruthenium organometallic compound supplied in the step 110 of the following cycle, thereby forming an additional ruthenium layer.

Examples of the inert gas include, but are not limited to, argon (Ar), nitrogen (N₂), and helium (He).

In the embodiment described above, two reactions for forming a ruthenium layer occur during a single deposition cycle. A first reaction for forming a ruthenium layer on the surface of a substrate occurs during the step 110, and a second reaction occurs during the step 130. On the other hand, in a typical ALD process, a single reaction occurs during a single deposition cycle. Accordingly, if the duration of one cycle is the same as that of the typical ALD process, the method of this embodiment can provide a deposition rate about twice as high as that of the typical ALD process. Nevertheless, with properly selected temperature conditions, each step can still have self-limiting effect and high conformality provided by true ALD reactions.

The cycle of the steps 110 to 140 can be repeated until a film of a desired thickness is formed. At step 150, it is determined whether a ruthenium layer having a desired thickness has been deposited. In one embodiment, it is determined how many cycles of deposition have been conducted. If the number of cycles has reached a selected number, the deposition may be terminated and the method may proceed to step 160 at which the substrate is unloaded from the reactor. If not, the deposition cycle 110-140 may be repeated. The selected number of cycles may be predetermined by trial and error. Alternatively, layer thickness can be monitored in real time to determine whether deposition is complete at decision box 150.

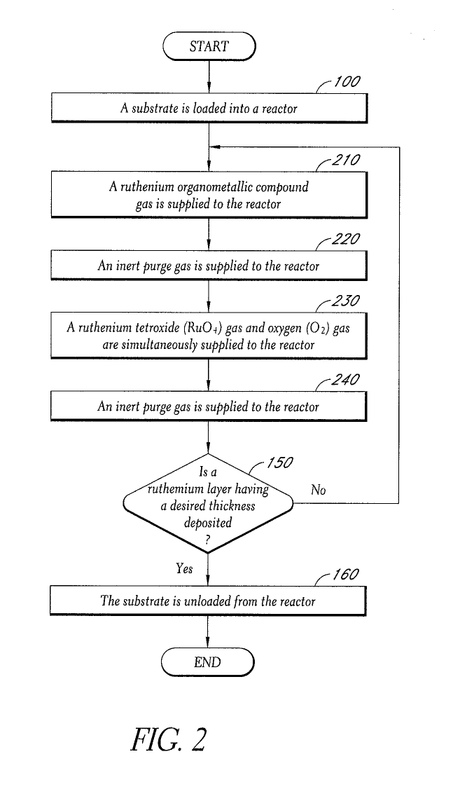

Referring to FIG. 2, a deposition method for formation of a ruthenium layer according to another embodiment will be now described. FIG. 2 is a flowchart illustrating a method of forming a ruthenium layer. In FIG. 2, the steps 100, 150, and 160 can be as described above with respect to the steps 100, 150, 160, respectively, of FIG. 1.

The illustrated method includes a cycle of sequential steps of: supplying a ruthenium organometallic compound gas to the reactor (step 210); supplying an inert purge gas to the reactor (step 220); supplying a ruthenium tetroxide (RuO₄) gas and oxygen (O₂) gas simultaneously to the reactor (step 230); and supplying an inert purge gas to the reactor (step 240). The cycle is repeated until a film of a desired thickness is formed.

FIG. 2 differs from FIG. 1 in that, during the step 230, the ruthenium tetroxide (RuO₄) gas and an oxidizing gas such as the oxygen (O₂) gas can be supplied simultaneously because they do not react with each other under the deposition conditions, thus preserving the self-limited, sequential nature of the ALD reactions.

In certain embodiments, the method may further include a step of supplying only oxygen (O₂) gas to the reactor after and/or before the step 230. This additional oxygen (O₂) gas may oxidize the ruthenium organometallic compound adsorbed on the surface of a substrate more effectively. In another embodiment, nitrous oxide (N₂O) gas, instead of oxygen (O₂) gas, may be supplied simultaneously with RuO₄ gas in the step 230, before the step 230 and/or after the step 230.

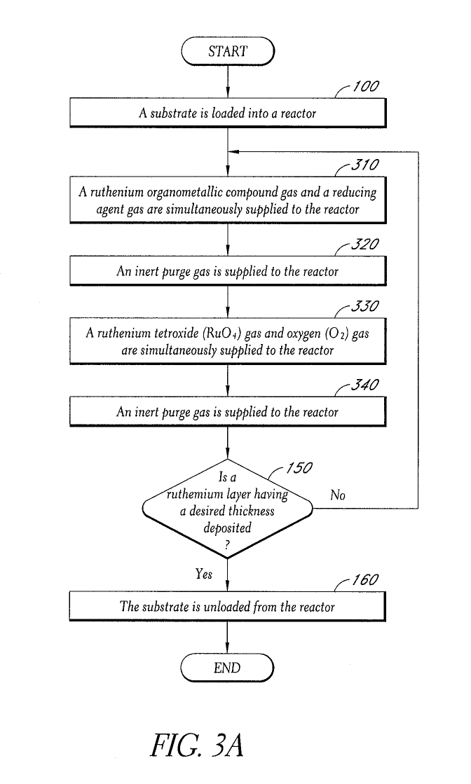

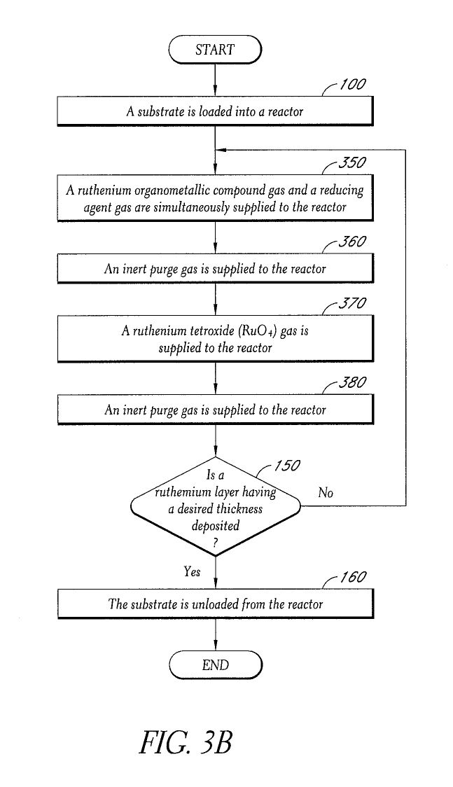

Referring to FIGS. 3A and 3B, deposition methods for forming a ruthenium layer according to other embodiments will be now described. FIGS. 3A and 3B are flowcharts illustrating methods of forming a ruthenium layer. In FIGS. 3A and 3B, the steps 100, 150, and 160 can be as described above with respect to the steps 100, 150, 160, respectively, of FIG. 1.

In FIG. 3A, the method includes a cycle of four sequential steps of: supplying a ruthenium organometallic compound gas and a reducing agent gas simultaneously to a reactor (step 310); supplying an inert purge gas to the reactor (step 320); supplying a ruthenium tetroxide (RuO₄) gas and oxygen (O₂) gas simultaneously to the reactor (step 330); and supplying an inert purge gas to the reactor (step 340). The details of the steps 320, 330, and 340 can be as described above with respect to those of the step 220, 230, and 240, respectively, of FIG. 2.

FIG. 3A differs from FIG. 2 in that, in the deposition method of FIG. 3A, during the step 310, the ruthenium organometallic compound gas and the reducing agent gas are simultaneously supplied to the reactor. Examples of the reducing agent gas include, but are not limited to, H₂, SiH₄, Si₂H₈, BH₃, and B₂H₆. During the step 310, the ruthenium organometallic compound gas and the reducing agent gas can be supplied simultaneously because they do not react with each other under the deposition conditions, such that the self-limited, sequential nature of the ALD reactions can be preserved. In certain embodiments, the method of FIG. 3A may further include a step of supplying only a reducing agent gas to the reactor after and/or before the step 310 of FIG. 3A. The additional reducing agent gas may reduce the ruthenium oxide including RuO₄ remaining on the substrate more effectively. In another embodiment, nitrous oxide (N₂O) gas, instead of oxygen (O₂) gas, may be supplied along with RuO₄ gas in the step 330.

In FIG. 3B, the method includes a cycle of four sequential steps including: supplying a ruthenium organometallic compound gas and a reducing agent gas simultaneously to the reactor (step 350); supplying an inert purge gas to the reactor (step 360); supplying a ruthenium tetroxide (RuO₄) gas to the reactor (step 370); and supplying an inert purge gas to the reactor (step 380). FIG. 3B differs from FIG. 3A in that step 370 can be as described above with respect to the step 130 of FIG. 1. Step 350 can be as described above with respect to step 310 of FIG. 3A, including optional additional pulses of reducing gas before and/or after step 310.

In the embodiments described above with reference to FIGS. 1, 2, 3A, and 3B, the deposition can be conducted at a reactor or substrate temperature of about 140° C. to about 500° C. The reactor pressure may be about several hundreds mTorr to several tens Torr. A skilled artisan will appreciate that the temperature and the pressure can be varied, depending on the reactants, reactor design, and thickness of a deposited film, substrate surface structure, etc.

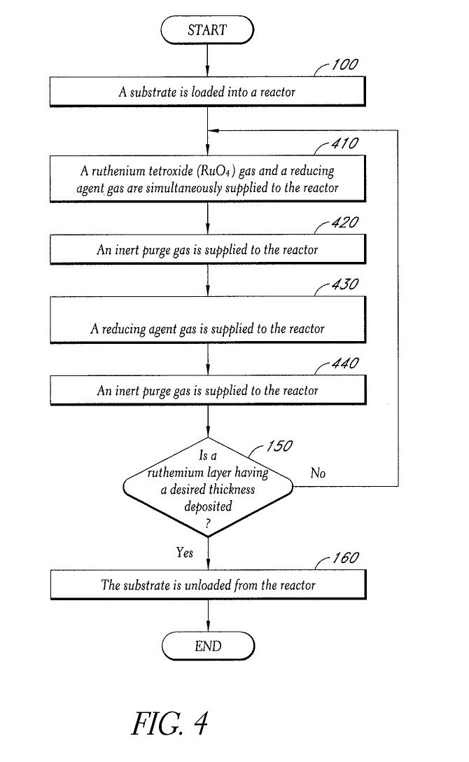

Referring to FIG. 4, a deposition method for formation of a ruthenium layer according to yet another embodiment will be now described. FIG. 4 is a flowchart illustrating a method of forming a ruthenium layer. In FIG. 4, the steps 100, 150, and 160 can be as described above with respect to the steps 100, 150, 160, respectively, of FIG. 1.

The illustrated method includes a cycle of four sequential steps of: supplying a ruthenium tetroxide (RuO₄) gas and a reducing agent gas simultaneously to the reactor (step 410); supplying an inert purge gas to the reactor (step 420); supplying a reducing agent gas to the reactor (step 430); and supplying an inert purge gas to the reactor (step 440). In one embodiment, the method can be conducted in a chemical deposition reactor. In one embodiment, the duration of the step 410 may be about one second to about ten seconds for a balance between conformality and rate of deposition as described below. The duration of the step 420 may be about one second to about ten seconds to ensure sufficient purging. The duration of the step 430 may be about one second to about ten seconds to reduce any remaining ruthenium oxide to ruthenium. The duration of the step 440 may be about 0 second to about 10 seconds. The other details of the purge steps 420 and 440 can be as described above with respect to those of the purge steps 120 and 140, respectively, of FIG. 1.

Examples of the reducing agent gas supplied during the step 410 include, but are not limited to, H₂, SiH₄, Si₂H₈, BH₃, and B₂H₆. In one embodiment, the cycle may be conducted at a temperature of about 140° C. to about 500° C. The reactor pressure may be about several hundreds mTorr to several tens Torr.

In this embodiment, a portion of the ruthenium tetroxide (RuO₄) gas is reduced to form a ruthenium oxide layer over a substrate in the form of RuOₓ (x≦2). The ruthenium oxide layer remains on the substrate. Next, any excess reactant and reaction by-products are purged from the reactor by supplying the inert purge gas to the reactor during the step 420. Then, the ruthenium oxide remaining on the substrate is reduced to ruthenium metal by the reducing agent gas supplied during the step 430. Finally, any excess reducing agent gas and reaction by-products are removed from the reactor by supplying the inert purge gas to the reactor during the step 440. The cycle is repeated until a ruthenium layer having a desired thickness is deposited on the substrate.

In the embodiments described above, one or more atomic layers of ruthenium can be deposited per deposition cycle. Accordingly, the ruthenium layer may be deposited more rapidly than typical ALD methods. In addition, the resulting ruthenium layer may have better step coverage on structures having a high aspect ratio than those deposited by chemical vapor deposition methods due to still maintaining some self-limited behavior for better conformality than CVD processes. A ruthenium layer having a thickness of about 0.1 Å to about 20 Å per cycle and step coverage of about 100% may be deposited by the method of FIG. 4.

In another embodiment, the step 440 may be omitted if the removal of any reaction by-products does not affect the quality of the deposited ruthenium layer after the step of supplying the reducing agent gas. In such an embodiment, the method includes one or more cycle(s) of three sequential steps of supplying a ruthenium tetroxide (RuO₄) gas and a reducing agent gas simultaneously to the reactor (step 410); supplying an inert purge gas to the reactor (step 420); and supplying a reducing agent gas to the reactor (step 430).

FIG. 4 may represent a controllable hybrid between ALD (high conformality and strictly self-limited deposition) and CVD (lower conformality due to deposition rates dependent on kinetics and/or mass flow). The deposition per cycle depends in part on the duration of step 410. For pulse durations much longer than 10 seconds, the process resembles CVD and its attendant nonuniformities. However, with pulse durations for step 410 between about 1 second and 10 seconds, good balance between ALD conformality and CVD deposition speed is obtained. Because the RuO₄ is only partially reduced to ruthenium oxide (RuOx, x<2) rather than fully reduced to ruthenium during step 410, some self-limited behavior ensures good conformality, while reduced duration of reduction step 430 is needed to accomplish full-reduction.

In the embodiments described above, the ruthenium layer may be deposited more rapidly than the typical atomic layer deposition method. The resulting ruthenium layer may have better step coverage on structures having a high aspect ratio than that deposited by a typical chemical deposition method.

### Electronic Devices

The embodiments described above may be used for forming ruthenium films that can be part of various electronic devices. Examples of the electronic device include, but are not limited to, electronic circuits, electronic circuit components, consumer electronic products, parts of the consumer electronic products, electronic test equipments, etc. The electronic circuit components may include, but are not limited to, integrated circuits such as a memory device, a processor, etc. The consumer electronic products may include, but are not limited to, a mobile phone, a telephone, a television, a computer monitor, a computer, a hand-held computer, a personal digital assistant (PDA), a microwave, a refrigerator, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi functional peripheral device, a wrist watch, a clock, etc. Further, the electronic device may include unfinished or partially fabricated products.

In at least some of the aforesaid embodiments, any element used in an embodiment can interchangeably be used in another embodiment unless such a replacement is not feasible. It will be appreciated by those skilled in the art that various other omissions, additions and modifications may be made to the methods and structures described above without departing from the scope of the invention. All such modifications and changes are intended to fall within the scope of the invention, as defined by the appended claims.

What is claimed is:

1. A method of depositing a ruthenium film on a substrate, the method comprising:
loading a substrate into a reactor; and
conducting a plurality of deposition cycles, each cycle comprising steps of:
supplying a ruthenium organometallic compound gas to the reactor;
supplying an inert purge gas to the reactor;
supplying a ruthenium tetroxide (RuO₄) gas to the reactor; and
supplying an inert purge gas to the reactor.

2. The method of claim 1, wherein supplying the ruthenium tetroxide (RuO₄) gas to the reactor comprises supplying the ruthenium tetroxide (RuO₄) gas simultaneously with an oxidizing gas selected from the group of oxygen (O₂) gas and nitrous oxide (N₂O) gas.

3. The method of claim 2, wherein each cycle further comprises supplying oxygen (O₂) gas to the reactor before and/or after supplying the ruthenium tetroxide (RuO₄) gas to the reactor.

4. The method of claim 1, wherein supplying the ruthenium organometallic compound comprises supplying the ruthenium organometallic compound simultaneously with a reducing agent gas.

5. The method of claim 4, wherein each cycle further comprises supplying a reducing agent gas to the reactor before and/or after supplying the ruthenium organometallic compound gas.

6. The method of claim 4, wherein supplying the ruthenium tetroxide (RuO₄) gas to the reactor comprises supplying the ruthenium tetroxide (RuO₄) gas simultaneously with an oxidizing gas selected from the group of oxygen (O₂) gas and nitrous oxide (N₂O) gas.

7. The method of claim 6, wherein each cycle further comprises supplying a reducing agent gas to the reactor before and/or after supplying the ruthenium organometallic compound gas.

8. The method of claim 1, wherein the duration of each of the steps is between about 0.2 seconds and about 10 seconds.

9. The method of claim 1, wherein the cycles are conducted at a substrate temperature between about 140° C. and about 500° C.

10. The method of claim 1, wherein the ruthenium organometallic compound comprises a cyclopentadienyl compound of ruthenium.

11. The method of claim 1, wherein the reactor comprises a chemical vapor deposition reactor.

12. The method of claim 1, wherein the substrate comprises a feature having an aspect ratio of about 2:1 or greater.

13. The method of claim 12, wherein the substrate comprises a feature having an aspect ratio of about 20:1 or greater.

14. The method of claim 13, wherein the substrate comprises a plurality of features with aspect ratios greater than about 20:1 in a partially fabricated memory array.

15. A method of making an electronic device, the method comprising:
providing a substrate into a reaction space; and
conducting a cyclical deposition on the substrate in the reaction space, each cycle comprising:
providing a ruthenium organometallic compound to the substrate;
removing any excess of the ruthenium organometallic compound from the reaction space;
providing ruthenium tetroxide (RuO₄) to the substrate; and
removing any excess of the ruthenium tetroxide from the reaction space.

16. The method of claim 15, wherein providing the ruthenium tetroxide (RuO₄) comprises supplying the ruthenium tetroxide (RuO₄) and an oxidizing gas selected from the group of oxygen (O₂) gas and nitrous oxide (N₂O) gas to the reaction space.

17. The method of claim 15, wherein providing the ruthenium organometallic compound comprises supplying the ruthenium organometallic compound and a reducing gas selected from the group consisting of a reducing agent gas to the reaction space.

18. The method of claim 17, wherein providing the ruthenium tetroxide comprises supplying the ruthenium tetroxide and an oxidizing gas selected from the group of oxygen (O₂) gas and nitrous oxide (N₂O) gas to the reaction space.

19. The method of claim 15, wherein each of removing any excess of the ruthenium organometallic compound and removing any excess of the ruthenium tetroxide comprises supplying purge gas.

20. A method of depositing a ruthenium film on a substrate, the method comprising:
loading a substrate in a reactor; and
conducting a plurality of deposition cycles, each cycle comprising in sequence:
supplying ruthenium tetroxide (RuO₄) gas and a reducing agent gas simultaneously to the reactor;
first supplying an inert purge gas to the reactor; and
supplying a reducing agent gas to the reactor.

21. The method of claim 20, wherein the reducing agent comprises at least one selected from the group consisting of H₂, SiH₄, Si₂H₈, BH₃, and B₂H₆.

22. The method of claim 20, wherein a duration of supplying the ruthenium tetroxide and the reducing agent is between about 1 second and about 10 seconds in each cycle.

23. The method of claim 20, wherein each cycle further comprises second supplying an inert purge gas to the reactor after supplying the reducing agent gas to the reactor.

24. The method of claim 23, wherein second supplying is conducted for less than about 10 seconds in each cycle.

25. The method of claim 20, wherein the cycles are conducted at a substrate temperature of about 140° C. to about 500° C.
